(19) United States
(12) Patent Application Publication
(10) Pub. No.: US 2002/0125929 A1
(43) Pub. Date: Sep. 12, 2002

(54) Clock duty cycle control circuit

(76) Inventors: Pi-Fen Chen, Taipei (TW); Chi-Ming Chen, Hsin-Chu City (TW)

Correspondence Address: LOWE HAUPTMAN GILMAN & BERNER, LLP, Suite 310, 1700 Diagonal Road, Alexandria, VA, 22314, US

(21) Appl. No.: 10/138,426

(22) Filed: May 6, 2002

Related U.S. Application Data
(63) Continuation-in-part of application No. 09/695,902, filed on Oct. 26, 2000.

(51) Int. Cl. H03K 3/017

(52) U.S. Cl. 327/175

(57) ABSTRACT

A clock duty cycle control circuit comprises a reference voltage circuit and a constant current generator connected to the reference voltage circuit. A duty-cycle adjustment circuit is used to receive a clock signal and controlled by the bias voltage of the bias voltage generating circuit which is connected to constant current generator. Accordingly, by a method of controlling duty-cycle adjustment circuit, the bias voltage has capability for adjusting a charging time and a discharging time of the clock signal. Finally, an open-drain driver with open-drain output is connected to the duty-cycle adjustment circuit, and thereby substantially stabilizing the output duty cycle of the clock signal.

This application is a continuation-in-part of U.S. patent application Ser. No. 09/695,902, filed Oct. 26, 2000.

### BACKGROUND OF THE INVENTION

1. Field of the Invention

The present invention relates to a clock generator, and more particularly, to a duty cycle control circuit with open-drain output.

2. Description of the Prior Art

A clock generator is conventionally used in a digital electronic system to synchronize the operations or processes performed therein. However, the stability of duty cycle (i.e., the percentage of its active duration over a complete cycle) largely depends on process variation, different internal supply voltage, and/or temperature variation. Accordingly, conventional digital electronic system sometimes functions incorrectly or even fails in a slightly abnormal environment, or needs great modification when adapting a disparate fabricating technique.

In order to overcome the aforementioned problem, separate circuit was proposed to compensate the temperature variation or the supply voltage variance separately. An overall solution to the problem is a conventional feedback control method that adjusts the duty cycle responding to its output. Nevertheless, such method increases the stability of its duty cycle at the loss of speed. That is, this type of clock generator could not adequately be applied in a high-speed application, such as that greater than 200 MHz. Moreover, these clock generators disadvantageously have limitation in application. For example, duty cycle can be easily controlled for conventional CMOS output open-drain driver. While for a high-speed open -drain driver with open drain output, there are greater variances for duty cycle under different environments.

Accordingly, there is a need for a duty cycle control circuit that substantially increases the stability of clock's duty cycle, and is substantially independent on process variation, different internal supply voltage, and temperature variation. In particular, such duty cycle control circuit is adaptable for the open-drain driver with open-drain output. Moreover, such duty cycle control circuit is applicable in high-speed applications.

### SUMMARY OF THE INVENTION

Accordingly, the present invention provides a duty cycle control circuit for high-speed applications. When the duty cycle is translated in high-speed clock, it is independent on process variation, different internal supply voltage, and temperature variation.

The other purpose of the present invention is to provide a duty cycle control circuit adaptable for an open-drain driver with open-drain output. The variance of the duty cycle is reduced by properly biasing the output path which combines the duty-cycle adjustment circuit and the open-drain-driver.

The duty cycle control circuit according to the present invention includes a circuit for generating a reference voltage, and a constant current generator connected to the reference voltage of the reference voltage generating circuit to provide a bias voltage. In usual, a band-gap reference circuit is used to generate a reference voltage of the present invention. A duty-cycle adjustment circuit is controlled by the bias voltage of the constant current generator, and adjusts the clock signal. Accordingly, the bias voltage controls the duty-cycle adjustment circuit so that charging and discharging time therein are under proper control. Finally, an open-drain driver with open-drain output is connected to the duty-cycle adjustment circuit. The overall circuits stabilize the output duty cycle of the clock. The duty cycle control circuit of the present invention comprises a bias generator, a duty cycle adjustment circuit, and an open drain driver, wherein the bias generator comprises a voltage generator, a constant current generator that comprises an operational amplifier, the first metal oxide semiconductor field effect transistor (MOSFET), the second MOSFET, the third MOSFET, and the first resistor, and a bias voltage generating circuit that comprises the fourth MOSFET. The duty cycle adjustment circuit comprises a clock, the fifth MOSFET, and the sixth MOSFET. The open-drain driver comprises the seventh MOSFET and the second resistor. The bias generator is coupled with the duty cycle adjustment circuit and the duty cycle adjustment circuit is coupled with the open drain driver. The voltage generator is coupled with the constant current generator and the constant current generator is coupled with the voltage bias generating circuit.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows a schematic diagram illustrating a clock duty cycle control circuit according to one embodiment of the present invention; and

FIG. 2 shows a schematic diagram detailing the embodiment as illustrated in FIG. 1.

### DESCRIPTION OF THE PREFERRED EMBODIMENT

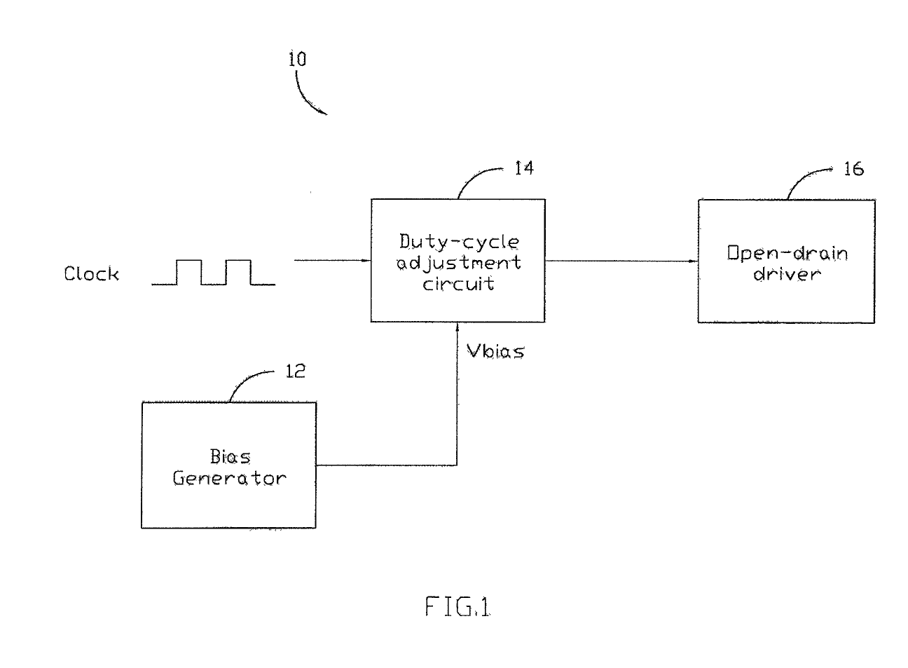

FIG. 1 shows a schematic diagram illustrating a clock duty cycle control circuit 10 according to one embodiment of the present invention. A bias generator 12 can generate and feed a bias voltage V_{bias} as to a duty-cycle adjustment circuit 14. By feeding the bias voltage, the charging time and discharging time of the duty-cycle adjustment circuit 14 are controlled so well that they can automatically adjust according to variations of parameters in process or outside environment. Furthermore, the duty-cycle adjustment circuit 14 has input configured to receive a clock signal named as Clock and an output connected to an open-drain driver 16.

The bias voltage V_{bias} of the bias generator 12, which is designed to automatically coordinate with the duty-cycle adjustment circuit 14 and the open-drain driver 16, can compensate variances of parameters in process, temperature and voltage, and further generate the clock output of a stable duty cycle (not shown). In particular, the clock output of the duty cycle is not influenced by process variation, internal supply voltages, and temperature variation of the control circuit 10. In the embodiment, the clock signal Clock is a Rambus-type clock signal, and the control circuit 10 is a clock chip in application to Rambus clock generator. It is appreciated that the present invention is not limited to the type of the clock signal used, and is not restricted its use to Rambus clock generation.

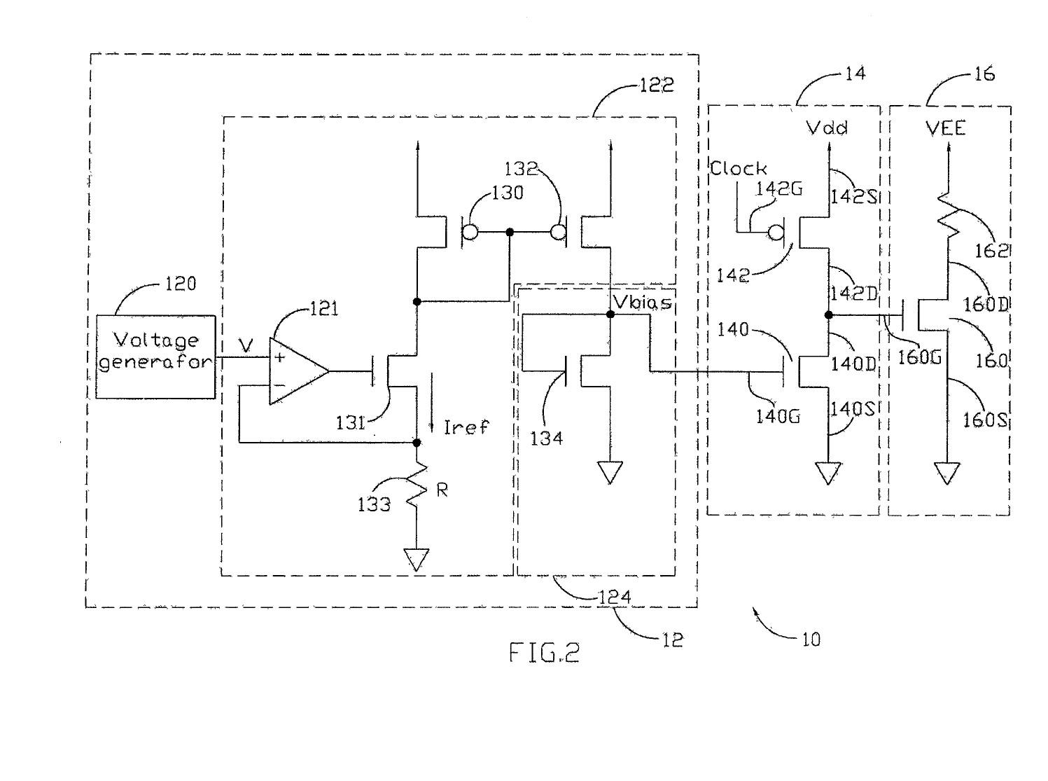

FIG. 2 shows a schematic diagram illustrating the embodiment of FIG. 1 in detail. In the preferred embodiment, the bias generator 12 is coupled with the duty-cycle adjustment circuit 14 and the duty-cycle adjustment circuit 14 is coupled with the open-drain driver 16. The bias generator 12 primarily comprises a voltage generator 120, a constant current generator 122, and a bias voltage generating circuit 124, wherein the voltage generator 120 is coupled with the constant current generator 122 and the bias voltage generating circuit 124 is coupled with the constant current generator 122 and the duty-cycle adjustment circuit 14. The constant current generator 122 comprises an operational amplifier 121, the first metal oxide semiconductor field effect transistor (MOSFET) 130, the second MOSFET 131, the third MOSFET 132, and the first resistor 133, and a bias voltage generating circuit 124 comprises the fourth MOSFET 134 which is the first type of MOSFET. The constant current generator 122 is used to output the constant current based upon a voltage. The bias voltage generating circuit 124 is used to generate a bias voltage based upon a constant current. The voltage generator 120 is coupled with the first end of the operational amplifier 121 which is in the constant current generator 122. The first MOSFET 130 comprises the first gate and the first source/drain region. The second MOSFET 131 comprises the second gate and the second source/drain region. The third MOSFET 132 comprises the third gate and the third source/drain region. The fourth MOSFET 134 comprises the fourth gate and the fourth source/drain region. The first MOSFET 130 is coupled with the second MOSFET 131 and the third MOSFET 132. The first gate of the first MOSFET 130 is coupled with the third gate of the third MOSFET 132. The second source/drain region is coupled with the second end of the operational amplifier 121 and is coupled with the first resistor 133. The second gate is further coupled with the third end of the operational amplifier 121 to transmit the voltage. The first interface between the first source/drain region and the second source/drain region is further coupled with the second interface between the first gate of the first MOSFET 130 and the third gate of the third MOSFET 132.

The voltage generator 120 is used to provide an independent voltage, which is stable and independent with temperature coefficient, when the control circuit is executed in a broad temperature range. In usual, a band-gap voltage generator is used to be the voltage generator 120 of the present invention and to output the voltage in account of affection of the circumstantial temperature of a open-drain driven. It is appreciated that the technique of the band-gap reference circuit 120 is well known in the art, and is purposely omitted here to its conciseness. Reference such as U.S. Pat. No. 4,939,442 discloses how a band-gap reference circuit 120 is designed and operated. It is further acknowledged that although a band-gap reference circuit 120 is used in this embodiment, other type of circuit that provides a stable reference voltage V_{BG} can be adaptably used. For example, the aforementioned US patent also discusses other reference voltage circuit, such as a buried-Zener reference circuit. Following needs of the products, the voltage generator also can be used to provide an independent voltage which is stable and dependent with temperature coefficient. The bias voltage generating circuit 124 is usually used to generate the voltage, which has specific process, temperature, and voltage coefficients, from the constant current generator 122. the fourth source/drain of the fourth MOSFET 134 is coupled with the third source/drain of the third MOSFET 132 and the fourth gate is coupled with the interface which is between the fourth source/drain and the third source/drain and is used to transmit V_{bias} to the duty cycle adjustment circuit 14. The constant current generator 122 is used for generating and further replicating a reference current I_{ref} that has a specific temperature coefficient.

The duty cycle adjustment circuit 14 comprises the fifth MOSFET 142, the sixth MOSFET 140, and a clock. The fifth MOSFET 142, which is the second type of MOSFET, comprises the fifth gate 142G and the fifth source/drain region 142S 142D and the sixth MOSFET 140, which is the first type of MOSFET, comprises the sixth gate 140G and the sixth source/drain region 140S 140D. The fifth drain 142D is coupled with the sixth drain 140D. The sixth gate 140G is coupled with the third interface between the fourth source/drain and the third source/drain. The third interface is further coupled with the fourth gate of the fourth MOSFET 134. The clock is coupled with the fifth gate 142 G to receive a clock signal. The clock rise/fall time (or duty cycle rise/full time) can be adjusted by V_{bias} and the output of the duty cycle adjustment circuit 14 is coupled with the open drain driver 16. The duty cycle adjustment circuit is used to receive a clock signal and outputting an adjusted clock signal having a transition time thereof been shifted based upon the bias voltage. The transition time is a fall time of the clock signal. The sixth MOSFET 140 is used to receiving the bias voltage and the fifth MOSFET is used to receive the clock signal and output the adjusted clock signal from a common drain of these two MOSFET.

The open-drain driver 16 comprises the seventh MOSFET 160, which is the first type of the MOSFET and the second resistor 162, wherein the seventh MOSFET comprises the seventh gate 160G and the seventh source/drain 160S 160D. The seventh drain 160 D is coupled with the second resistor 162 and the seventh gate 160G is coupled with the fourth interface between the fifth drain 142D and the sixth drain 140D. In the embodiment, the seventh drain 160D is an open drain, so as to connect to any external resistor 162. The open drain driver 16 is used to receive the adjusted clock signal and output a normal driving clock. The shifted transition time of the adjusted clock signal will be compensated by the threshold voltage of the open-drain driver so that the normal driving clock will have a correct transition time.

In the present invention, the first MOSFET 130, the second MOSFET 131, the third MOSFET 132, the fourth MOSFET 134, the fifth MOSFET 142, the sixth MOSFET 140, and the seventh MOSFET 160 can use N-type MOSFET or P-type MOSFET, but the fourth MOSFET 134, the sixth MOSET 140, and the seventh MOSFET 160 must use the same type MOSFET to control an output voltage conforming with needs of the user. In usual, the N-type MOSFET is used in the fourth MOSFET 134, the sixth MOSET 140, and the seventh MOSFET 160 and the P-type MOSFET is used in the fifth MOSFET 142.

In the present invention, a threshold voltage of the fourth MOSFET 134 will affect its output bias voltage (V_{bias}) because of factors of the process and processing parameters of the threshold voltage of the fourth MOSFET 134, a threshold voltage of the sixth MOSFET 140, and a threshold voltage of the open-drain are the same, therefore the collocation of the elements of the clock duty cycle control circuit of the present invention can offset (adjust) the deviating form which is caused by the rise/fall time of the clock signal from the open drain driver and output a adjusted clock signal whose duty cycle is balance and is conforming to the needs of the process. Furthermore, the open drain driver can get a clock duty cycle control circuit which has compensations of the temperature and process parameters without effects from the power supply.

According to the embodiment described above, it is noted that the present invention provides a duty cycle control circuit for improving the stability of duty cycle against process variation, different internal supply voltage, and temperature variation. For example, some tests illustrate that the control circuit of the present invention has a duty cycle in a range about from 47.1% to 51.9% while a conventional circuit has the duty cycle with approximately 20% variance. Furthermore, the duty cycle control circuit of the present invention is adaptable for, but not limited to, a open-drain driver with open-drain output. Moreover, such duty cycle control circuit is applicable in a high-speed application, such as that greater than 200 MHz.

In accordance with the present invention, the present invention provides a duty cycle control circuit for high-speed applications. The duty cycle control circuit of the present invention includes a circuit for generating a reference voltage, and a constant current generator connected to the reference voltage of the reference voltage generating circuit to provide a bias voltage. In usual, a band-gap reference circuit is used to generate a reference voltage of the present invention. A duty-cycle adjustment circuit is controlled by the bias voltage of the bias voltage generating circuit which is connected to the constant current generator, and adjusts the clock signal. Accordingly, the bias voltage controls the duty-cycle adjustment circuit so that charging and discharging time therein are under proper control. Finally, an open-drain driver with open-drain output is connected to the duty-cycle adjustment circuit. The overall circuits stabilize the output duty cycle of the clock. The duty cycle control circuit of the present invention comprises a bias generator, a duty cycle adjustment circuit, and an open drain driver, wherein the bias generator comprises a voltage generator, a constant current generator that comprises an operational amplifier, the first metal oxide semiconductor field effect transistor (MOSFET), the second MOSFET, the third MOSFET, and the first resistor, and a bias voltage generating circuit that comprises the fourth MOSFET being diode connected. The duty cycle adjustment circuit comprises the fifth MOSFET for receiving a clock and the sixth MOSFET. The open-drain driver comprises the seventh MOSFET and the second resistor. The bias generator is coupled with the duty cycle adjustment circuit and the duty cycle adjustment circuit is coupled with the open drain driver. The voltage generator is coupled with the constant current generator and the constant current generator is coupled with the voltage bias generating circuit.

Although specific embodiments have been illustrated and described, it will be obvious to those skilled in the art that various modifications may be made without departing from what is intended to be limited solely by the appended claims.

What is claimed is:

1. A clock duty cycle control circuit, comprising:
a bias voltage generating circuit for generating a bias voltage based upon a constant current;
a duty cycle adjustment circuit for receiving a clock signal and outputting an adjusted clock signal having a transition time thereof been shifted based upon the bias voltage; and
an open-drain driver for receiving the adjusted clock signal and outputting a normal driving clock;
wherein the shifted transition time of the adjusted clock signal will be compensated by the threshold voltage of the open-drain driver so that the normal driving clock will have a correct transition time.

2. The circuit of claim 1, further comprising a constant current generator for outputting the constant current based upon a voltage.

3. The circuit of claim 2, further comprising a band-gap voltage generator for outputting the voltage in account of affection of the circumstantial temperature of the open-drain driven.

4. The circuit of claim 1, wherein the transition time is a fall time of the clock signal.

5. The circuit of claim 1, wherein the bias voltage generating circuit comprises a first type of MOSFET being diode connected.

6. The circuit of claim 5, wherein the duty cycle adjusting circuit comprises a first type of MOSFET for receiving the bias voltage and a second type of MOSFET for receiving the clock signal and outputs the adjusted clock signal from a common drain of the two MOSFET.

7. The circuit of claim 6, wherein the open-drain driver comprises a first type of MOSFET.

8. The circuit of claim 7, wherein all of the first type of MOSFET have the same process parameters.

9. A clock duty cycle control circuit, wherein said clock duty cycle control circuit comprises:
a voltage generator wherein said voltage generator is used to provide a voltage;
a constant current generator, wherein said constant current generator is coupled with said voltage generator and comprises an operational amplifier, a first MOSFET, a second MOSFET, and a third MOSFET;
a bias voltage generating circuit, wherein said bias voltage generating circuit is coupled with said constant current generator and comprises a fourth MOSFET;
a duty cycle adjustment circuit, wherein said duty cycle adjustment circuit is coupled with an interface between said constant current generator and said bias voltage generating circuit and comprises a clock, a fifth MOSFET, and a sixth MOSFET whose type is as same as said fourth MOSFET; and
an open drain driver, wherein said open drain driver is coupled with said duty cycle adjustment circuit and comprises a seventh MOSFET whose type is as same as said fourth MOSFET and said sixth MOSFET.

10. The clock duty cycle control circuit according to claim 9, wherein said voltage generator comprises a band-gap reference circuit.

11. The clock duty cycle control circuit according to claim 9, wherein said fourth MOSFET is a N-type MOSFET.

12. The clock duty cycle control circuit according to claim 9, wherein said fifth MOSFET is a P-type MOSFET.

13. The clock duty cycle control circuit according to claim 9, wherein said clock is a high speed clock.

14. A clock duty cycle control circuit, wherein said clock duty cycle control circuit comprises:
a voltage generator, wherein said voltage generator is used to provide a voltage;
a constant current generator, wherein said constant current generator is coupled with said voltage generator and comprises:
an operational amplifier, a first end of said operational amplifier is coupled with said voltage generator;
a first MOSFET, wherein said first MOSFET comprises a first gate and a first source/drain region;
a second MOSFET, wherein said second MOSFET is coupled with said first MOSFET and comprises:
a second source/drain region, wherein said second source/drain region is coupled with a second end of said operational amplifier and said first source/drain region;
a second gate, wherein said second gate is coupled with a third end of said operational amplifier;
a third MOSFET, said third MOSFET comprising a third gate and a third source/drain, wherein said third gate is coupled with said first gate and a first interface between said first source/drain and said second source/drain is coupled with a second interface between said first gate and said third gate;
a first resistor, said first resistor is coupled with said second MOSFET;
a bias voltage generating circuit, said bias voltage generating circuit being coupled with said constant current generator and comprising a fourth MOSFET, which comprises a fourth gate and a fourth source/drain, wherein said fourth source/drain is coupled with said third source/drain and a third interface between said fourth source/drain and said third source/drain is coupled with said fourth gate; a duty cycle adjustment circuit, said duty cycle adjustment circuit being coupled with said third interface, wherein said duty cycle adjustment circuit comprises:
a fifth MOSFET, said fifth MOSFET comprising a fifth gate, a fifth source, and a fifth drain;
a sixth MOSFET, said sixth MOSFET comprising a sixth gate, a sixth source, and a sixth drain, wherein said sixth drain is coupled with said fifth drain, said sixth gate is coupled with said third interface, and a type of said sixth MOSFET is as same as said fourth MOSFET;
a clock, wherein said clock is coupled with said fifth gate to provide a clock signal; and
an open drain driver, said open drain driver comprising a seventh MOSFET, which comprises a seventh gate, seventh source, and seventh drain, and a second resistor and being coupled with said duty cycle adjustment circuit, wherein said seventh gate is coupled with a fourth interface between said fifth drain and said sixth drain and said second resistor is coupled with said seventh drain.

15. The clock duty cycle control circuit according to claim 14, wherein said voltage generator comprises a band-gap reference circuit.

16. The clock duty cycle control circuit according to claim 14, wherein said fourth MOSFET is a N-type MOSFET.

17. The clock duty cycle control circuit according to claim 14, wherein said fourth MOSFET is a P-type MOSFET.

18. The clock duty cycle control circuit according to claim 14, wherein said fifth MOSFET is a P-type MOSFET.

19. The clock duty cycle control circuit according to claim 14, wherein said fifth MOSFET is a N-type MOSFET.

20. The clock duty cycle control circuit according to claim 14, wherein said clock is a high speed clock.
